(19) United States
(12) Patent Application Publication
(10) Pub. No.: US 2026/0018436 A1
(43) Pub. Date: Jan. 15, 2026

(54) SUBSTRATE PROCESSING APPARATUS

(71) Applicant: SHIBAURA MECHATRONICS CORPORATION, Yokohama-shi (JP)

(72) Inventors: Rie TESHIMA, Yokohama-shi (JP); Jun MATSUSHITA, Yokohama-shi (JP); Hiroaki KOBAYASHI, Yokohama-shi (JP)

(73) Assignee: SHIBAURA MECHATRONICS CORPORATION, Yokohama-shi (JP)

(21) Appl. No.: 19/256,224

(22) Filed: Jul. 1, 2025

(30) Foreign Application Priority Data
Jul. 9, 2024 (JP) 2024-110529

(51) Int. Cl. H01L 21/67

(52) U.S. Cl. CPC H01L 21/67115; H01L 21/67075; H01L 21/67248

(57) ABSTRACT

A substrate processing apparatus, includes: a rotary holder configured to hold and rotate a substrate; a processing liquid supply configured to supply a processing liquid to the substrate held and rotated by the rotary holder; a heater including a heat source configured to heat the substrate or the processing liquid in contact with the substrate in a non-contact manner; a temperature measurer arranged at a position facing the rotary holder and configured to measure a temperature of a heating target object heated by the heater in a non-contact manner; and a stop controller configured to stop supply of electric power to the heater when it is determined that the temperature measured by the temperature measurer exceeds a preset temperature.

### CROSS-REFERENCE TO RELATED APPLICATION

This application is based upon and claims the benefit of priority from Japanese Patent Application No. 2024-110529, filed on Jul. 9, 2024, the entire contents of which are incorporated herein by reference.

### TECHNICAL FIELD

The present disclosure relates to a substrate processing apparatus.

### BACKGROUND

There is known a single-substrate-type substrate processing apparatus that supplies a processing liquid to a substrate such as a semiconductor wafer while rotating the substrate, and performs an etching process, a resist removal process, or the like. In such substrate processing apparatus, the substrate and the processing liquid on the substrate under processing are heated by a heating device, thereby increasing the temperature of the processing liquid and improving the processing efficiency.

In such a heating device, it is necessary to heat the substrate and the processing liquid on the substrate in a non-contact manner so that the cleanliness of the substrate is not deteriorated by contact with a heat source. For example, non-contact heating can be achieved by using a light emitting element such as an LED that irradiates the substrate with heating light as the heat source of the heating device.

However, when the substrate or the processing liquid is heated by a non-contact heat source, the constituent members constituting the substrate processing apparatus are also heated. For example, among the constituent members that rotate the substrate, holding members such as chuck pins that hold the substrate are also heated. The constituent members heated in this manner may be overheated due to the long heating time, the high heating temperature, the malfunction of the heat source, or other reasons. This may cause a breakdown due to the deformation of the overheated constituent members.

### SUMMARY

Some embodiments of the present disclosure provide a substrate processing apparatus capable of preventing constituent members from being overheated.

According to one embodiment of the present disclosure, there is provided a substrate processing apparatus, including: a rotary holder configured to hold and rotate a substrate; a processing liquid supply configured to supply a processing liquid to the substrate held and rotated by the rotary holder; a heater including a heat source configured to heat the substrate or the processing liquid in contact with the substrate in a non-contact manner; a temperature measurer arranged at a position facing the rotary holder and configured to measure a temperature of a heating target object heated by the heater in a non-contact manner; and a stop controller configured to stop supply of electric power to the heater when it is determined that the temperature measured by the temperature measurer exceeds a preset temperature.

### BRIEF DESCRIPTION OF DRAWINGS

The accompanying drawings, which are incorporated in and constitute a part of the specification, illustrate embodiments of the present disclosure.

FIG. 1 is a partial axial cross-sectional view showing a processing liquid being supplied in a substrate processing apparatus according to an embodiment.

FIG. 2 is a partial axial cross-sectional view showing a rinsing liquid being supplied in the substrate processing apparatus of FIG. 1.

FIG. 3 is a partial axial cross-sectional view showing a substrate being loaded and unloaded in the substrate processing apparatus of FIG. 1.

FIG. 4 is a bottom view showing a heater and a member thermometer.

FIG. 5 is a block diagram of a controller.

FIG. 6 is a flowchart showing a procedure of a substrate processing process according to an embodiment.

FIG. 7 is a flowchart showing a procedure of a temperature monitoring process according to an embodiment.

FIG. 8 is a bottom view showing a modification of the arrangement of the heater and the member thermometer.

FIG. 9 is a partial cross-sectional view of the substrate processing apparatus showing a modification of the arrangement of the member thermometer.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment of the present disclosure will be described with reference to the drawings.

### Overview

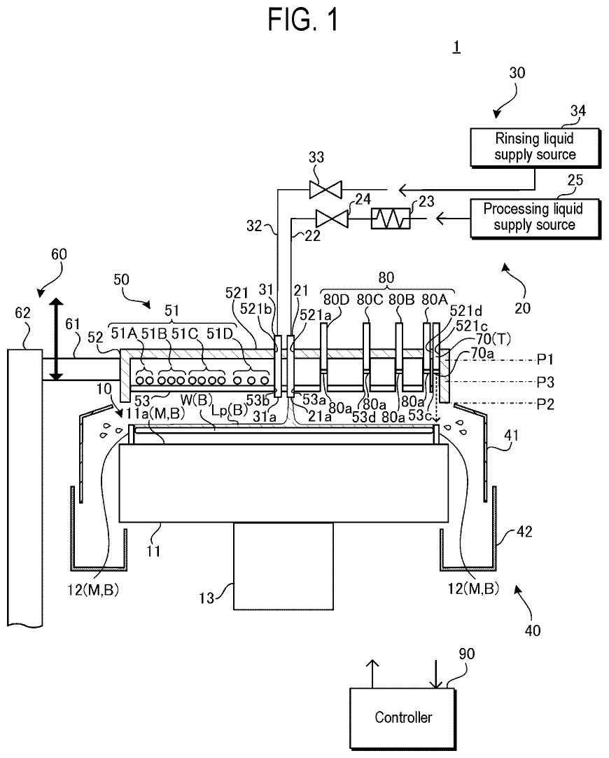

As shown in FIG. 1, a substrate processing apparatus 1 processes a substrate W by supplying a processing liquid Lp from a processing liquid supply 20 to the substrate W while rotating the substrate W held by a rotary holder 10. The substrate processing apparatus 1 according to this embodiment is a single-wafer-type apparatus that performs an etching process by supplying the processing liquid Lp having an etching ability to the substrate W. During the etching process, a heater 50 heats the substrate W, thereby maintaining the processing liquid Lp supplied to the substrate W at a high temperature and improving the processing efficiency.

Furthermore, a temperature measurer T arranged at a position facing the rotary holder 10 measures the temperature of heating target objects B heated by the heater 50 in a non-contact manner. The heating target objects B include the substrate W and the processing liquid Lp. The heating target objects B also includes objects that are heated together with the substrate W and the processing liquid Lp. In this embodiment, the constituent members M constituting the rotary holder 10 are included in the heating target objects B. For example, an opposing surface 11a of a rotary table 11 constituting the rotary holder 10 and the holding member 12 that holds the substrate W are the constituent members M and the objects B. Furthermore, a controller 90 of the substrate processing apparatus 1 prevents overheating of the constituent members M by monitoring the temperature measured by the temperature measurer T.

The substrate W processed in this embodiment is, for example, a disk-shaped silicon wafer (hereinafter referred to as a Si substrate) having a silicon nitride film and a silicon oxide film formed on its surface. The processing liquid Lp is, for example, an aqueous solution including phosphoric acid (hereinafter referred to as a phosphoric acid solution). The concentration of phosphoric acid in the processing liquid Lp is, for example, 85 to 94 wt %. A rinsing liquid Lc is, for example, pure water (H₂O).

### Configuration

As shown in FIG. 1, the substrate processing apparatus 1 according to this embodiment includes a rotary holder 10, a processing liquid supply 20, a rinsing liquid supply 30, a liquid receiver 40, a heater 50, a lifting mechanism 60, a member thermometer 70 (temperature measurer T), a processing liquid thermometer 80, and a controller 90.

### (Rotary Holder)

The rotary holder 10 holds and rotates the substrate W. The rotary holder 10 includes the rotary table 11, holding members 12, and a driver 13. The rotary table 11 is a cylindrical member, one end of which is closed by the opposing surface 11a. The opposing surface 11a is a circular surface having a larger diameter than the substrate W, and faces the substrate W as a target with a gap interposed between the opposing surface 11a and the substrate W.

The holding members 12 are members that hold the substrate W with the gap interposed between the substrate W and the opposing surface 11a of the rotary table 11. The holding members 12 in this embodiment are chuck pins that protrude above the rotary table 11, and are provided at equal intervals along the position corresponding to the outer periphery of the substrate W. The holding members 12 are provided so as to be movable by an opening/closing mechanism (not shown) between a closed position where the holding members 12 come into contact with the outer periphery of the substrate W to hold the substrate W, and an open position where the holding members 12 move away from the outer periphery of the substrate W to release the substrate W. The holding members 12 may have any form as long as they can hold the substrate W. For example, the holding members 12 may be hook-shaped members that rotate toward and away from the substrate W.

The driver 13 is a drive source (motor) that rotates the rotary table 11. The driver 13 rotates the rotary table 11, thereby rotating the substrate W held by the holding members 12.

### (Processing Liquid Supply)

The processing liquid supply 20 supplies the processing liquid Lp to the substrate W held and rotated by the rotary holder 10. The processing liquid supply 20 includes a processing liquid nozzle 21, a processing liquid supply pipe 22, a heater 23, and a valve 24. The processing liquid nozzle 21 is inserted through a support portion 52 and a cover 53 of the heater 50 described later, and is provided so that the discharge port 21a at the tip of the processing liquid nozzle 21 faces a vicinity of the center of the substrate W held by the rotary holder 10.

The processing liquid nozzle 21 is connected to a processing liquid supply source 25, such as a tank in which the processing liquid Lp is stored, via the processing liquid supply pipe 22. In this embodiment, the processing liquid Lp delivered from the processing liquid supply source 25 is heated in advance. The heater 23 is provided in the middle of the processing liquid supply pipe 22. The processing liquid Lp delivered from the processing liquid supply source 25 is moved through the processing liquid supply pipe 22, is heated by the heater 23, and is then delivered from the discharge port 21a of the processing liquid nozzle 21 to the vicinity of the center of the substrate W.

The temperature of the processing liquid Lp discharged from the processing liquid nozzle 21 is, for example, 160 degrees C. Furthermore, the valve 24 is provided in the middle of the processing liquid supply pipe 22. By opening and closing the valve 24, the discharge of the processing liquid Lp from the processing liquid nozzle 21 is started and stopped. The valve 24 is electrically connected to a controller 90, which will be described later, and the opening and closing of the valve 24 is controlled by the controller 90.

### (Rinsing Liquid Supply)

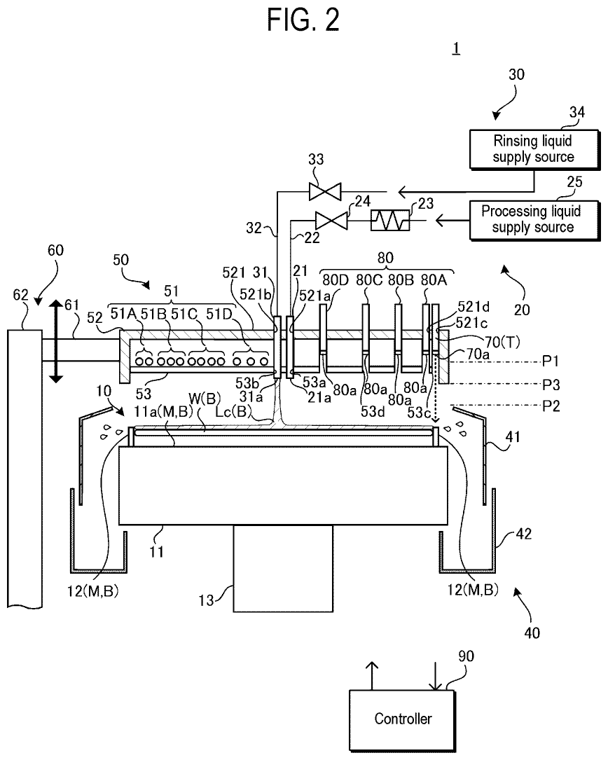

As shown in FIG. 2, the rinsing liquid supply 30 supplies the rinsing liquid Lc to the substrate W held by the rotary holder 10. For example, pure water may be used as the rinsing liquid Lc. The rinsing liquid supply 30 includes a rinsing liquid nozzle 31, a rinsing liquid supply pipe 32, and a valve 33. The rinsing liquid nozzle 31 is inserted through the support portion 52 and the cover 53 of the heater 50 described later, and is provided so that the discharge port 31a at the tip of the rinsing liquid nozzle 31 faces the vicinity of the center of the substrate W held by the rotary holder 10.

The rinsing liquid nozzle 31 is connected to a rinsing liquid supply source 34, such as a tank in which the rinsing liquid Le is stored, via the rinsing liquid supply pipe 32. The rinsing liquid Lc sent from the rinsing liquid supply source 34 is moved through the rinsing liquid supply pipe 32 and is discharged from the discharge port 31a of the rinsing liquid nozzle 31 toward the center of the substrate W. The valve 33 is provided midway along the rinsing liquid supply pipe 32. The discharge of the rinsing liquid Lc from the rinsing liquid nozzle 31 is started and stopped by opening and closing the valve 33. The valve 33 is electrically connected to the controller 90, which will be described later, and the opening and closing of the valve 33 is controlled by the controller 90.

### (Liquid Receiver)

The liquid receiver 40 is provided to surround the rotary holder 10 and is configured to receive the processing liquid Lp and rinsing liquid Le scattered from the rotating substrate W. The liquid receiver 40 discharges the received processing liquid Lp and the rinsing liquid Le to the outside of the substrate processing apparatus 1.

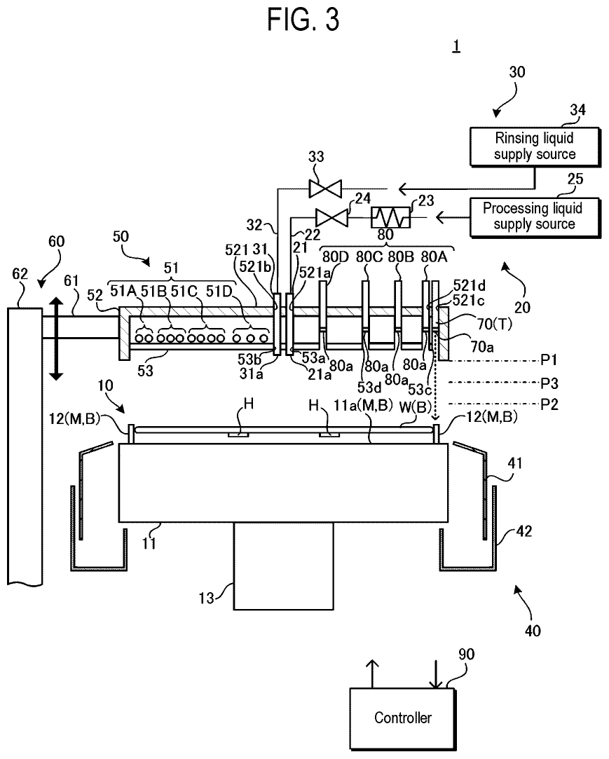

The liquid receiver 40 includes a cup portion 41 and a receiving portion 42. The cup portion 41 is a cylindrical body that covers the periphery of the rotary holder 10 with a gap left between the cup portion 41 and the rotary holder 10, and is bent so that the diameter of the upper portion thereof becomes small. The cup portion 41 is provided so as to be movable between a standby position (see FIG. 3) and a processing position (see FIGS. 1 and 2) by a lifting mechanism (not shown). The receiving portion 42 is provided below the cup portion 41 and is an annular container that is open at the top thereof.

The processing liquid Lp and the rinsing liquid Le scattered from the substrate W are received by the cup portion 41. The processing liquid Lp and the rinsing liquid Le fall downward along the inner wall of the cup portion 41, and then flow into the receiving portion 42. The processing liquid Lp and the rinsing liquid Le that flow into the receiving portion 42 are discharged to the outside of the substrate processing apparatus 1 from a discharge port (not shown) formed in the bottom surface of the receiving portion 42.

### (Heater)

The heater 50 includes a heat source 51 that heats the substrate W in a non-contact manner. The heat source 51 is capable of heating the substrate W by receiving electric power (power supply). The heat source 51 is, for example, a light-emitting element that emits heating light. The heat source 51 irradiates the substrate W held and rotated by the rotary holder 10 with light, thereby heating the substrate W. The processing liquid Lp supplied in the vicinity of the center of the substrate W flows so as to spread toward the outer edge of the substrate W due to the centrifugal force. At this time, if there is no further heating, the temperature of the supplied processing liquid Lp of a high temperature (160 degrees C.) decreases as it flows on the substrate W due to heat conduction and heat dissipation to the substrate W. Therefore, by heating the substrate W, the processing liquid Lp on the substrate W can be heated by heat conduction from the substrate W, and the processing liquid Lp on the substrate W can be maintained at a high temperature. The output of the heater 50 may be controlled not only to maintain the temperature of the processing liquid Lp but also to further increase the temperature on the substrate W.

The light-emitting element used as the heat source 51 emits light (electromagnetic waves) having a wavelength that is absorbed by the substrate W to heat the substrate W. The light emitted by the heat source 51 is light having a wavelength that is transmitted through the processing liquid Lp. As used herein, the expression “absorbed by the substrate W” means that the light incident on the substrate W is absorbed to an extent that the substrate W can be sufficiently heated, and includes not only complete absorption by the substrate W, but also a part of the light being reflected or transmitted by the substrate W. The expression “transmitted through the processing liquid Lp” means that the light incident on the processing liquid Lp is transmitted through the processing liquid Lp to an extent that the substrate W can be sufficiently heated, and includes a portion of the light being absorbed or reflected by the processing liquid Lp.

As the light-emitting element, for example, an LED that emits heating light is used. The wavelength of the light emitted by this LED is, for example, 350 nm to 1060 nm (350 nm or more and 1060 nm or less). More preferably, the central wavelength is 395 nm to 940 nm (395 nm or more and 940 nm or less). In this embodiment, an LED having a central wavelength of 395 nm is used.

As a result, even if the light from the heat source 51 is irradiated from above the space in which the substrate W is held, i.e., from above the processing liquid Lp supplied to the substrate W, the light can penetrate the processing liquid Lp on the substrate W and can be absorbed by the substrate W, thereby heating the substrate W. Then, the temperature of the processing liquid Lp increases due to thermal conduction from the substrate W, thereby increasing the etching rate (processing rate). The start and stop of heating by the heat source 51 and the output of the heat source 51 are controlled by the controller 90, which will be described later. The start and stop of power supply to the heat source 51 according to the temperature measured by the temperature measurer T are also controlled by the controller 90, which will be described later.

The heater 50 includes a support portion 52 and a cover 53 in addition to the above-mentioned heat source 51. The support portion 52 is a member that supports a plurality of heat sources 51. The support portion 52 is a cylindrical member whose upper end is closed by a top plate 521. The diameter of the support portion 52 is equal to or larger than the diameter of the substrate W. The support portion 52 is disposed above the rotary table 11 at a position facing the opposing surface 11a with a gap left between the support portion 52 and the opposing surface 11a. As a result, the heater 50 is provided so that the light from the heat source 51 is irradiated from above the space in which the substrate W is held by the rotary holder 10. In addition, two through-holes 521a and 521b are provided in a vicinity of the center of the top plate 521 of the support portion 52.

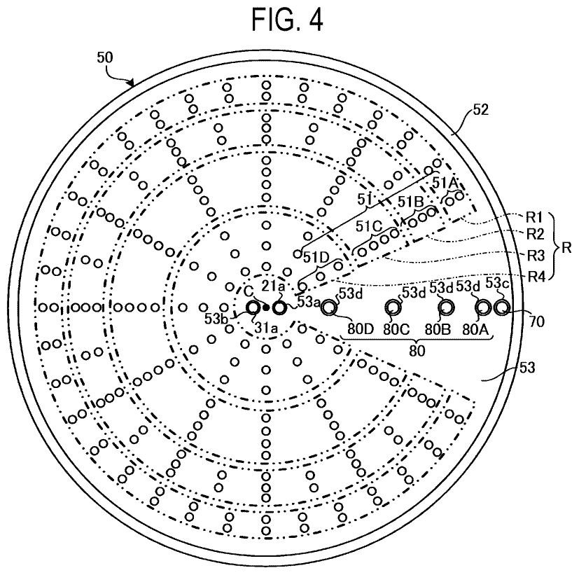

As shown in FIG. 4, the cover 53 is a disk-shaped member that covers the end of the support portion 52 facing the rotary table 11. The cover 53 is made of a material that is resistant to the processing liquid Lp, and is configured to transmit the light emitted from the heat source 51. For example, a quartz cover 53 is used. Two through-holes 53a and 53b are formed in a vicinity of the center C of the cover 53. In FIG. 4, the heat source 51 that can be seen through the cover 53 is shown by a solid line.

As shown in FIG. 1, the processing liquid nozzle 21 is inserted through the through-holes 521a and 53a so that the discharge port 21a at the tip of the processing liquid nozzle 21 is exposed from the cover 53 to face the substrate W. The rinsing liquid nozzle 31 is inserted through the through-holes 521b and 53b so that the discharge port 31a at the tip of the rinsing liquid nozzle 31 is exposed from the cover 53 to face the substrate W.

A plurality of heat sources 51 are attached to the support portion 52 so as to face the rotary table 11 with the cover 53 interposed between the heat sources 51 and the rotary table 11. The heater 50 has a plurality of regions in which the heat sources 51 are arranged. That is, the plurality of heat sources 51 is arranged and distributed in a plurality of regions. In this embodiment, the heat sources 51 are provided in regions corresponding to different radial positions of the substrate W, and the output of the heat sources 51 can be controlled for each region. Furthermore, the plurality of heat sources 51 is arranged so as to be able to irradiate light onto an entire target surface of the substrate W.

For example, as shown in FIG. 4, a plurality of heat sources 51A to 51D is arranged in four concentric annular regions R1 to R4 (indicated by two-dot chain lines in the figure) so that the output can be controlled for each of the regions R1 to R4. Each of the regions R1 to R4 excludes a fan-shaped region in which a processing liquid thermometer 80 (described later) is arranged. No heat source 51 is arranged in the fan-shaped region. In the following description, when the regions R1 to R4 are not distinguished from one another, they are simply referred to as regions R. Furthermore, when the heat sources 51A to 51D are not distinguished from one another, they are simply referred to as heat sources 51.

In FIG. 4, the intervals between the heat sources 51 corresponding to the boundaries of the regions R are shown as being large in order to make the regions R easier to distinguish. However, as long as the regions R to be controlled are distinguished from one another, the intervals between the heat sources 51 may all be uniform. The number of heat sources 51 is also not limited to that shown in FIG. 4. For example, several hundred to several thousand heat sources 51 may be arranged densely all over. By rotating the substrate W relative to the heat sources 51, the entire substrate W can be irradiated with light, thereby heating the entire surface of the substrate W.

### (Lifting Mechanism)

As shown in FIG. 1, the lifting mechanism 60 supports and lifts the heater 50. The lifting mechanism 60 includes an arm 61 and a support column 62. The arm 61 is a member extending in a direction parallel to the substrate W. One end of the arm 61 is connected to an outer peripheral portion of the support portion 52. The support column 62 stands in a direction perpendicular to the substrate W to support the other end of the arm 61. The support column 62 is provided so as to be movable up and down by a drive source such as a ball screw mechanism or a cylinder (not shown).

The heater 50 is positioned at any one of heights, i.e., a loading/unloading position P1, a heating position P2 and a rinsing position P3, by driving the lifting mechanism 60. The respective positions are as follows.
Loading/unloading position P1: a height position spaced apart upward from the rotary table 11 so that a hand H of a transfer robot can be inserted (see FIG. 3).
Heating position P2: a height position closer to the substrate W than the loading/unloading position P1 (see FIG. 1), at which the heater does not come into contact with the processing liquid Lp on the substrate W.
Rinsing position P3: a height position between the loading/unloading position P1 and the heating position P2 (see FIG. 2).

### (Member Temperature)

As shown in FIG. 1, the substrate processing apparatus according to this embodiment includes a member thermometer 70 as the temperature measurer T. The member thermometer 70 measures the temperature of constituent members M, which are the heating target objects B. As described above, the constituent members M include the opposing surface 11a and the holding member 12. For example, a radiation thermometer is used as the member thermometer 70. The radiation thermometer is a thermometer that focuses light (electromagnetic waves) emitted from an object on a detection element and outputs an electrical signal according to the temperature. The radiation thermometer of this embodiment measures the temperature of the constituent members M in a non-contact manner based on the light emitted from the constituent members M. More specifically, the light emitted from the constituent members M is received by a light receiver 70a, and the temperature of the constituent members M is calculated according to the light intensity.

The member thermometer 70 is provided at a position facing the holding member 12 of the rotary holder 10 when the rotary holder 10 is stopped. In other words, the member thermometer 70 is disposed so that the temperature measurement range thereof includes the stopped holding member 12. This enables the member thermometer 70 to detect the temperature of the holding member 12 while the rotary holder 10 is stopped.

Furthermore, while the rotary holder 10 is rotating, the member thermometer 70 arranged at such a position faces a position on the circumference of the opposing surface 11a, which is the movement path of the holding member 12. Therefore, while the rotating holding unit 10 is rotating, the member thermometer 70 can detect the temperature of the holding member 12 and the opposing surface 11a. In this embodiment, there is one member thermometer 70. As described above, the rotary holder 10 is heated while rotating. Therefore, there is a high possibility that the holding members 12 on a common circumferential portion are heated equally. Therefore, it is sufficient to be able to measure the temperature of one representative holding member 12. However, as described later, multiple member thermometers 70 may be arranged.

The member thermometer 70 is provided at a position where the temperature of a vicinity of the outermost periphery of the region heated by the heat sources 51 can be measured. More specifically, as shown in FIG. 4, the member thermometer 70 is provided on a circumference outside the outermost peripheral region among the regions where the heat sources 51 are provided. This position is a vicinity of the outer side of a processing liquid thermometer 80A provided at the outermost periphery among a plurality of processing liquid thermometers 80 to be described later. Since the temperature of the processing liquid Lp supplied to and spread on the substrate W is likely to decrease at such a position, it is highly likely that the heating temperature of the heat source 51 will increase. Then, the temperature of the heating target objects B heated by the heat source 51 is likely to be the highest at this position. Therefore, the object B in the region where the temperature is likely to be the highest, for example, the holding member 12, is the measurement target of the member thermometer 70.

In this embodiment, the member thermometer 70 is fixed to the support portion 52. More specifically, as shown in FIGS. 1 and 4, the through-holes 521c and 53c are formed at positions facing the holding member 12 in vicinities of the outer edges of the cover 53 and the support portion 52. The through-hole 521c of the support portion 52 and the through-hole 53c of the cover 53 are provided directly above the stopping position of the holding member 12.

The member thermometer 70 is inserted into the through-hole 521c and fixed such that the light receiver 70a thereof faces the stopped holding member 12 via the through-hole 53c. The member thermometer 70 is electrically connected to the controller 90. The member thermometer 70 transmits measured values to the controller 90 while the substrate processing apparatus 1 is operating.

The measurement wavelength of the member thermometer 70 is a wavelength capable of measuring the intensity the light emitted from the holding member 12 and the opposing surface 11a, which are the constituent members M. The measurement wavelength of the member thermometer 70 is preferably different from the wavelength of the light emitted by the heat source 51. By setting the measurement wavelength of the member thermometer 70 to the wavelength different from the wavelength of the light emitted by the heat source 51, it is possible to prevent stray light from being generated with respect to the member thermometer 70 and to suppress measurement errors.

For example, the measurement wavelength of the member thermometer 70 is preferably 8 μm to 14 μm (8 μm or more and 14 μm or less). This measurement wavelength is different from the wavelength of the light emitted by the heat source 51, and is a wavelength that allows temperature measurement for both the holding member 12 and the rotary table 11. The emissivity of the member thermometer 70 is preferably set to the emissivity of the heating target object B that is most likely to be heated by the heater 50 among the heating target objects B within the measurement range. For example, when the material of the holding member 12, which is the constituent member M, is carbon fiber-reinforced PTFE (polytetrafluoroethylene), the emissivity thereof is set.

### (Processing Liquid Thermometer)

The processing liquid thermometer 80 measures the temperature of the processing liquid Lp that is heated in contact with the substrate W. The processing liquid thermometer 80 is, for example, a radiation thermometer. The processing liquid thermometer 80 of this embodiment measures the temperature of the processing liquid Lp in a non-contact manner based on the light emitted from the processing liquid Lp. More specifically, the light emitted from the processing liquid Lp is received by a light receiver 80a, and the temperature of the processing liquid Lp is calculated according to the light intensity.

Processing liquid thermometers 80 are provided at positions corresponding to the multiple regions R, respectively. That is, the number of radiation thermometers provided corresponds to the number of regions R. In this embodiment, four processing liquid thermometers 80A to 80D are fixed to the support portion 52 so as to correspond to the regions R1 to R4. When the processing liquid thermometers 80A to 80D are not to be distinguished from one another, they are simply referred to as processing liquid thermometers 80.

More specifically, as shown in FIGS. 1 and 4, through-holes 521d and 53d are formed in the fan-shaped regions of the cover 53 and the support portion 52 where the heat sources 51 are not arranged, and in the circumferences corresponding to the respective regions R1 to R4 where the heat sources 51 are arranged. Four through-holes 521d of the support portion 52 and four through-holes 53d of the cover 53 are provided so as to correspond to the four regions R1 to R4, respectively.

Each of the processing liquid thermometers 80A to 80D is inserted into the corresponding through-hole 521d, and is fixed such that the light receiver 80a thereof faces the substrate W held by the rotary holder 10 via each through-hole 53d. The processing liquid thermometer 80 is electrically connected to the controller 90. In this embodiment, the four processing liquid thermometers 80 and the member thermometer 70 are arranged in a straight line along the radial direction of the support portion 52 (substrate W). The member thermometer 70 is arranged in the vicinity of the processing liquid thermometer 80A arranged on the outermost periphery.

The measurement wavelength of the processing liquid thermometer 80 is a wavelength capable of measuring the intensity of the light emitted from the processing liquid Lp. It is also preferable that the measurement wavelength of the processing liquid thermometer 80 and the wavelength of the light emitted by the heat source 51 are different. By making the measurement wavelength of the processing liquid thermometer 80 and the wavelength of the light emitted by the heat source 51 different, it is possible to prevent stray light from being generated with respect to the processing liquid thermometer 80 and to suppress measurement errors.

For example, when the processing liquid Lp is a phosphoric acid solution, it is preferable that the measurement wavelength of the processing liquid thermometer 80 is 2.2 μm to 2.4 μm (2.2 μm or more and 2.4 μm or less). In this embodiment, the measurement wavelength is 2.3 μm. The wavelength 2.2 μm to 2.4 μm is a wavelength at which the intensity ratio between the phosphoric acid solution and water is large. By using such a wavelength as the measurement wavelength of the processing liquid thermometer 80, even if water vapor is generated during processing, the influence of the water vapor can be suppressed and the temperature of the processing liquid Lp can be measured.

Furthermore, the measurement wavelength of the processing liquid thermometer 80 is different from the measurement wavelength of the member thermometer 70. For example, as described above, if the measurement wavelength of the processing liquid thermometer 80 is set to 2.2 μm to 2.4 μm, it differs from the measurement wavelength of the member thermometer 70, which is 8 μm to 14 μm.

### (Controller)

The controller 90 controls each part of the substrate processing apparatus 1. The controller 90 includes a processor that executes a program to realize various functions of the substrate processing apparatus 1, a memory that stores various information such as programs and operating conditions, and a drive circuit that drives each element. In other words, the controller 90 controls the rotary holder 10, the processing liquid supply 20, the rinsing liquid supply 30, the liquid receiver 40, the heater 50, the lifting mechanism 60, the member thermometer 70 (temperature measurer T), the processing liquid thermometer 80, and the like.

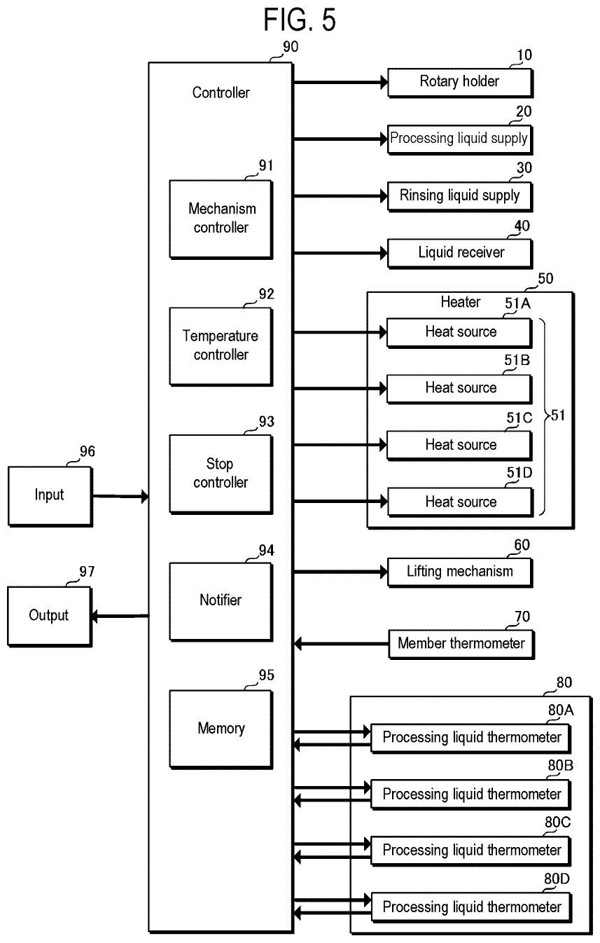

More specifically, as shown in FIG. 5, the controller 90 includes a mechanism controller 91, a temperature controller 92, a stop controller 93, a notifier 94, and a memory 95. The mechanism controller 91 controls the operations of mechanism parts such as the opening/closing mechanism of the rotary holder 10, the driver 13, the heater 23 and the valve 24 of the processing liquid supply 20, the valve 33 of the rinsing liquid supply 30, the lifting mechanism of the liquid receiver 40, the lifting mechanism 60, and the like.

The temperature controller 92 controls the temperature of the substrate W heated by the heater 50 based on the temperature of the processing liquid Lp measured by the processing liquid thermometer 80. The processing liquid thermometer 80 corrects the measured light intensity based on the emissivity of the processing liquid Lp stored in advance in the memory 95, and calculates the temperature of the processing liquid Lp on the substrate W. Then, the processing liquid thermometer 80 transmits the calculated temperature to the controller 90. The temperature controller 92 adjusts the light intensity of the heat source 51 of the heater 50 so that the temperature of the processing liquid Lp becomes a target temperature, thereby heating the substrate W. At this time, the temperature of the processing liquid Lp in each of the regions R1 to R4 is controlled by adjusting the light intensity of each of the heat sources 51A to 51D according to the temperature of the processing liquid Lp measured by the processing liquid thermometers 80A to 80D in each of the regions R1 to R4. That is, the controller 90 controls the output of the heat source 51 for each of the regions R based on the temperature of the substrate W measured by the processing liquid thermometer 80.

The stop controller 93 stops the supply of electric power (power supply) to the heater 50 when it is determined that the temperature measured by the member thermometer 70, which is the temperature measurer T, exceeds a preset temperature. The preset temperature is determined based on the heat resistance temperature of the material of the constituent members M so as to be lower than the temperature at which abnormalities such as deformation and the like occur. For example, the preset temperature is determined based on the heat resistance temperature of the material of the holding member 12 or the material of the rotary table 11. The preset temperature may be set according to the lower heat resistance temperature. In addition, the stop controller 93 instructs the mechanism controller 91 to stop the processing operation of the substrate processing apparatus 1 until a predetermined operation is performed by an operator. For example, the stop controller 93 stops the rotation of the rotary holder 10, the supply of the processing liquid Lp, the supply of the rinsing liquid Lc, the loading of the substrate W, and the like.

When it is determined that the temperature measured by the member thermometer 70, which is the temperature measurer T, exceeds the preset temperature, the notifier 94 causes the output 97, which will be described later, to output an alarm notifying that there is an abnormality in the temperature. The memory 95 stores information necessary for processing in each part of the substrate processing apparatus 1. For example, the memory 95 stores the target temperature of the processing liquid Lp, the emissivity of the processing liquid Lp, the emissivity of the holding member 12, the preset temperature, the alarm information, and the like.

An input 96 and an output 97 are connected to the controller 90. The input 96 is composed of, for example, a touch panel, a keyboard, a mouse, a switch, etc. Through the input 96, an operator can input information necessary for processing the substrate W, such as an instruction to turn on (start) or turn off (stop) the power supply of the substrate processing apparatus 1, an instruction to start or stop substrate processing, an instruction to start or stop heating of the heater 50, an instruction to start or stop supplying electric power to the heater 50, a target temperature of the processing liquid Lp, an emissivity of the processing liquid Lp, an emissivity of the holding member 12, and a preset temperature.

The output 97 is composed of, for example, a display, a speaker, a buzzer, a lamp, and the like. In accordance with an instruction from the notifier 94, the output 97 outputs an alarm to notify the operator. For example, the output 97 may display an image notifying an abnormality on a display, sound an alarm through a speaker or a buzzer, or turn on or off a lamp, or blink the lamp.

### [Operation]

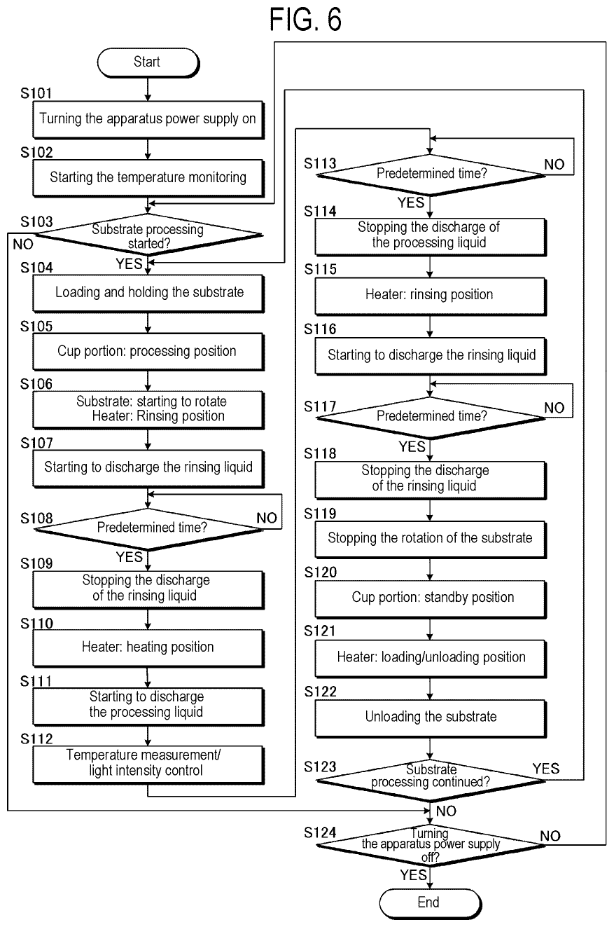

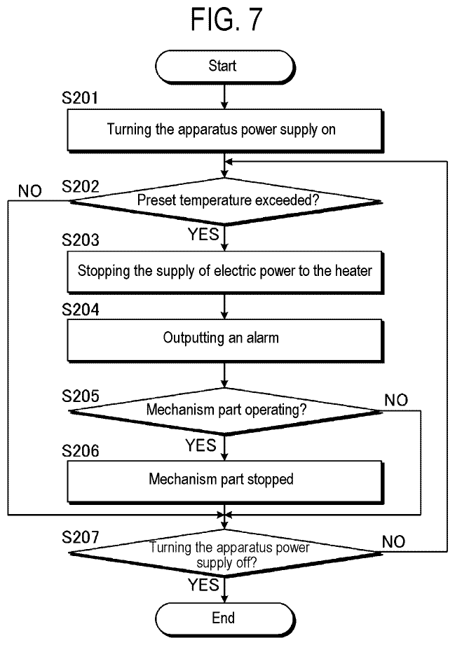

The operation of the substrate processing apparatus 1 according to this embodiment will be described with reference to the flowcharts of FIGS. 6 and 7 in addition to FIGS. 1 to 5. A substrate processing method for processing a substrate W and a temperature monitoring method for the substrate processing apparatus 1 according to the following procedure are also aspects of this embodiment.

### (Substrate Processing)

First, the overall procedure of substrate processing will be described with reference to FIG. 6. As shown in FIG. 3, the heater 50 is located in advance at the loading/unloading position P1, and the cup portion 41 is located at the standby position. The valve 24 of the processing liquid supply 20 and the valve 33 of the rinsing liquid supply 30 are closed. In addition, the rotary holder 10 is stopped, and the holding member 12 faces the member thermometer 70.

When the power supply of the substrate processing apparatus 1 is turned on (step S101), the controller 90 starts temperature monitoring (step S102). That is, the member thermometer 70 transmits the detected temperature of the constituent members M to the controller 90, and the controller 90 continues or stops the power supply to the heater 50 depending on the temperature. This temperature monitoring process is performed until the power supply of the substrate processing apparatus 1 is turned off. The details will be described later.

When an instruction to start substrate processing is input (YES in step S103), the holding member 12 is brought to the open position, and the substrate W mounted on the hand H (see FIG. 3) of the transfer robot is loaded between the heater 50 and the rotary table 11. Then the holding member 12 is brought to the closed position, so that the periphery of the substrate W is supported by the holding member 12. As a result, the substrate W is held on the opposing surface 11a of the rotary table 11 with a gap left between the substrate W and the opposing surface 11a (step S104). At this time, the substrate W is positioned so that the center of the substrate W coincides with the rotation axis of the rotary table 11. The cup portion 41 is then lifted and located at the processing position (step S105).

Next, as shown in FIG. 2, the rotary table 11 rotates, so that the substrate W held by the holding member 12 starts to rotate, and the heater 50 is lowered and located at the rinsing position P3 (step S106).

Then, the valve 33 of the rinsing liquid supply 30 is opened, and the rinsing liquid Le is discharged from the rinsing liquid nozzle 31 to the vicinity of the center of the substrate W (step S107). When the rinsing liquid Lc is supplied to the rotating substrate W, the rinsing liquid Lc moves sequentially toward the outer periphery of the substrate W, and spreads over the entire target surface of the substrate W.

Without such supply of the rinsing liquid Lc, when the processing liquid Lp is supplied, the processing liquid Lp does not spread over the entire target surface of the substrate W due to surface tension, resulting in uneven processing. In this embodiment, in order to prevent such uneven processing, the rinsing liquid Lc is supplied in this step before the processing liquid Lp is supplied. When a predetermined rinsing time (a preset time) has elapsed (YES in step S108), the valve 33 of the rinsing liquid supply 30 is closed and the discharge of the rinsing liquid Lc from the rinsing liquid nozzle 31 is stopped (step S109).

Next, as shown in FIG. 1, the heater 50 starts to move downward and stops when it reaches the heating position P2 (step S110). Then, the valve 24 of the processing liquid supply 20 is opened, and the processing liquid Lp is discharged from the processing liquid nozzle 21 to the vicinity of the center of the substrate W (step S111). When the processing liquid Lp is supplied to the rotating substrate W, the processing liquid Lp moves sequentially toward the outer periphery of the substrate W and spreads over the entire target surface of the substrate W. Since the rinsing liquid Lc has been supplied to the target surface of the substrate W in advance, the processing liquid Lp spreads over the entire target surface of the substrate W, thereby preventing uneven processing.

With the start of the discharge of the processing liquid Lp, the heating of the substrate W by the irradiation of light from the heat source 51 and the measurement of the temperature of the processing liquid Lp by the processing liquid thermometer 80 are started. During the heating of the substrate W, the temperature controller 92 of the controller 90 feedback-controls the output of the heat source 51 based on the temperature measurement result for the processing liquid Lp, so as to maintain the temperature of the processing liquid Lp on the substrate W at a target temperature (step S112). Even if water vapor (H₂O) is generated by heating, the measurement wavelength of the processing liquid thermometer 80 has a small water absorbance. Therefore, the influence of the water vapor is suppressed and the temperature of the processing liquid Lp can be measured. The process of heating the substrate W while supplying the processing liquid Lp to the substrate W is continued until a predetermined processing time (preset time) has elapsed (NO in step S113).

When the predetermined processing time has elapsed (YES in step S113), the valve 24 of the processing liquid supply 20 is closed to stop the supply of the processing liquid Lp from the processing liquid nozzle 21 (step S114). At the same time, the heating by the heat source 51, i.e., the light irradiation, and the temperature measurement by the processing liquid thermometer 80 are stopped.

As shown in FIG. 2, the heater 50 starts to move upward and stops when it reaches the rinsing position P3 (step S115). Then, the valve 33 of the rinsing liquid supply 30 is opened, and the rinsing liquid Lc is discharged from the rinsing liquid nozzle 31 to the vicinity of the center of the substrate W (step S116). When the rinsing liquid Lc is supplied to the rotating substrate W, the rinsing liquid Lc moves sequentially toward the outer periphery of the substrate W and spreads over the entire target surface of the substrate W.

When the rinsing liquid Lc is supplied to the processing liquid Lp, which is a phosphoric acid solution, a large amount of water vapor is generated. At this time, since the heater 50 is at the rinsing position P3, which is a position farther away from the substrate W than the heating position P2, it is possible to suppress adhesion of water vapor to the heater 50. In addition, since the rinsing position P3 is a position closer to the substrate W than the loading/unloading position P1, it is possible to suppress liquid splashing, and to suppress adhesion of liquid droplets to the heater 50.

When a predetermined rinsing time (a preset time) has elapsed (YES in step S117), the valve 33 of the rinsing liquid supply 30 is closed, and the discharge of the rinsing liquid Le from the rinsing liquid nozzle 31 is stopped (step S118). The rotary table 11 is stopped to stop the rotation of the substrate W held by the holding member 12 (step S119). Thereafter, the cup portion 41 is lowered and located at the standby position (step S120).

As shown in FIG. 3, the heater 50 is moved upward and located at the loading/unloading position P1 (step S121). In this state, the hand H of the transfer robot is inserted below the substrate W, and the holding member 12 is placed at the open position. Thus, the substrate W is placed on the hand H of the transfer robot and unloaded to the outside (step S122). At this time, the rinsing liquid Le is held on the substrate W.

If there is a next target substrate W and an instruction to stop the substrate processing is not input, the substrate processing apparatus 1 continues the substrate processing (YES in step S123). That is, the processing in steps S104 to S122 is repeated. If there is no next target substrate W or an instruction to stop the substrate processing is input, the substrate processing apparatus 1 does not continue the substrate processing (NO in step S123). Then, if the power supply of the substrate processing apparatus 1 is turned off (YES in step S124), the substrate processing ends. The substrate processing also ends if the substrate processing is not started (NO in step S103) and the power supply of the substrate processing apparatus 1 is turned off (YES in step S124).

### (Temperature Monitoring Process)

Next, the procedure for monitoring the temperature of the constituent members M, which are the heating target objects B, in the above-described substrate processing will be described with reference to the flowchart shown in FIG. 7. As described above, when the power supply of the substrate processing apparatus 1 is turned on (step S201), the controller 90 continues to receive the temperature of the constituent members M measured by the member thermometer 70. When the power supply of the substrate processing apparatus 1 is turned on, the supply of electric power to the heater 50 is started. If the received temperature is equal to or lower than the preset temperature (NO in step S202), the supply of electric power to the heater 50 is continued. In this way, the temperature monitoring continues while the power supply of the substrate processing apparatus 1 is kept turned on (NO in step S207).

When it is determined that the received temperature exceeds the preset temperature (YES in step S202), the stop controller 93 stops the supply of electric power to the heater 50 (step S203). As a result, when the substrate processing apparatus 1 is performing substrate processing by supplying the processing liquid Lp, the heating of the processing liquid Lp by the heater 50 is stopped, thereby preventing overheating. In addition, even if the heating by the heater 50 is not stopped due to a malfunction or if the heating by the heater 50 has already been started due to a malfunction, when the preset temperature is exceeded, the supply of electric power to the heater 50 is stopped and the heating by the heater 50 is stopped, thereby preventing overheating.

In response to an instruction from the notifier 94, the output 97 outputs an alarm notifying that there is an abnormality in temperature (step S204). Furthermore, if the mechanism parts of the substrate processing apparatus 1 are operating (YES in step S205), the stop controller 93 instructs the mechanism controller 91 to stop the operation of the mechanism parts (step S206). For example, the mechanism controller 91 stops the rotation of the rotary holder 10, the supply of the processing liquid Lp from the processing liquid supply 20, and the loading of the next substrate W. In response to such an alarm and operation stop, the operator inspects the substrate processing apparatus 1. Thereafter, the substrate processing is stopped until the operator inputs an instruction to start the supply of electric power to the heater 50 and an instruction to start substrate processing.

Even when heating is not being performed by the heater 50, if it is determined that the received temperature exceeds the preset temperature (YES in step S202), the stop controller 93 determines that a certain abnormality has occurred, and stops the supply of electric power to the heater 50 (step S203), the output 97 outputs an alarm (step S204), and the operation of the mechanism parts of the substrate processing apparatus 1 is stopped (step S206). As a result, even if a heating instruction is issued from the controller 90 due to a malfunction, an erroneous operation, or the like, the heater 50 that is not supplied with electric power does not start heating. If the power supply of the substrate processing apparatus 1 is turned off (YES in step S207), the temperature monitoring ends.

### Effects

(1) The substrate processing apparatus 1 according to this embodiment includes a rotary holder 10 configured to hold and rotate a substrate W, a processing liquid supply 20 configured to supply a processing liquid Lp to the substrate W held and rotated by the rotary holder 10, a heater 50 including a heat source 51 configured to heat the substrate W or the processing liquid Lp in contact with the substrate W in a non-contact manner, a temperature measurer T arranged at a position facing the rotary holder 10 and configured to measure a temperature of a heating target object B heated by the heater 50 in a non-contact manner, and a stop controller 93 configured to stop supply of electric power to the heater 50 when it is determined that the temperature measured by the temperature measurer T exceeds a preset temperature.

Therefore, the heating target object B heated when heating the substrate W and the processing liquid Lp by the non-contact heat source 51 can be prevented from overheating even if the heating time becomes long, the heating temperature becomes high, or the heat source 51 undergoes a malfunction. Therefore, it is possible to prevent the occurrence of failures due to deformation of an overheated object B.

Furthermore, if a thermocouple or the like is provided inside the rotary table 11 to measure the temperature of the heating target object B, the wiring for the thermocouple becomes complicated and the maintenance becomes troublesome. However, in this embodiment, the temperature measurer T arranged at the position facing the rotary holder 10 measures the temperature of the heating target object B in a non-contact manner. Therefore, the device configuration is simplified and maintenance is easy.

(2) The heating target object B includes a constituent member M constituting the rotary holder 10, and the temperature measurer T includes a member thermometer 70 configured to measure the temperature of the constituent member M. Therefore, it is possible to prevent deformation due to overheating of the constituent member M such as the holding member 12, the opposing surface 11a of the rotary table 11 or the like.

(3) The member thermometer 70 is a radiation thermometer configured to measure the temperature of the constituent member M based on the light emitted from the constituent member M of the rotary holder 10. Therefore, the temperature of the rotationally moved constituent member M can be measured in a non-contact manner. In addition, since the surface of the heating target object B is heated by the heat source 51 in a non-contact manner, the temperature of the surface of the heating target object B is likely to rise suddenly. Then, for example, when the temperature is measured using a thermocouple arranged inside the rotary table 11, a difference is likely to occur between the timing of the temperature rise and the timing of the measurement thereof. In this embodiment, the temperature of the surface of the heating target object B is measured by the member thermometer 70, which is a radiation thermometer. Therefore, a delay in the temperature measurement is less likely to occur, and overheating can be prevented.

(4) The heat source 51 is a light emitting element configured to emit light having a wavelength that is absorbed by the substrate W, and the wavelength of the light emitted by the light emitting element is different from the measurement wavelength of the member thermometer 70. For example, the processing liquid Lp supplied by the processing liquid supply 20 is an aqueous solution including phosphoric acid, the light emitted by the light emitting element has a wavelength in a range of 350 nm to 1060 nm, and the measurement wavelength of the member thermometer 70 is 8 μm to 14 μm. This prevents stray light and suppresses measurement errors.

(5) The substrate processing apparatus 1 further includes a processing liquid thermometer 80 configured to measure the temperature of the processing liquid Lp supplied to the rotating substrate W in a non-contact manner, and a temperature controller 92 configured to control the temperature of the substrate W heated by the heater 50 based on the temperature of the processing liquid Lp measured by the processing liquid thermometer 80. The processing liquid thermometer 80 is a radiation thermometer configured to measure the temperature of the processing liquid Lp based on light emitted from the processing liquid Lp, and the measurement wavelength of the processing liquid thermometer 80 is different from the measurement wavelength of the member thermometer 70. For example, the measurement wavelength of the processing liquid thermometer 80 is 2.2 μm to 2.4 μm, and the measurement wavelength of the member thermometer 70 is 8 μm to 14 μm.

Therefore, even if the processing liquid thermometer 80 and the member thermometer 70 have to be arranged in a narrow region or in close proximity to each other, the temperatures of the respective target objects can be measured, thereby reducing measurement errors.

(6) The heat source 51 is a light emitting element configured to emit light having a wavelength that is absorbed by the substrate W, and the wavelength of the light emitted by the light emitting element is different from the measurement wavelength of the processing liquid thermometer 80 and the measurement wavelength of the member thermometer 70. For example, the processing liquid Lp supplied by the processing liquid supply 20 is an aqueous solution including phosphoric acid, the light emitted by the light emitting element has a wavelength in a range of 350 nm to 1060 nm, the measurement wavelength of the processing liquid thermometer 80 is 2.2 μm to 2.4 μm, and the measurement wavelength of the member thermometer 70 is 8 μm to 14 μm. This prevents stray light and suppresses measurement errors.

(7) The rotary holder 10 includes a holding member 12 configured to hold the substrate W, and the member thermometer 70 is provided at a position facing the holding member 12 of the rotary holder 10 when the rotary holder 10 is stopped. Therefore, the temperature of the holding member 12, which may cause problems in holding and rotating the substrate W when the holding member 12 is deformed by heating, can be monitored to prevent such problems from occurring.

(8) The rotary holder 10 has an opposing surface 11a facing the substrate W, and the member thermometer 70 is provided at a position facing the opposing surface 11a. Therefore, if the opposing surface 11a is deformed by heating, the temperature of the opposing surface 11a, which may cause problems in rotating the substrate W, can be monitored to prevent such problems from occurring.

(9) The heat source 51 includes a plurality of heat sources 51 provided in regions corresponding to different radial positions of the substrate W, the output of each of the heat sources can be controlled for each of the regions, and the member thermometer 70 is provided at a position where the member thermometer 70 can measure the temperature of a vicinity of the outermost periphery of the region heated by the heat sources 51. Since the temperature of the processing liquid Lp is likely to drop in the vicinity of the outermost periphery, there is a tendency for the heating temperature of the heat sources 51 to be high, and therefore there is a high possibility that the corresponding constituent member M will be overheated. By measuring the temperature at such a position, the member thermometer 70 can prevent the constituent member M from being overheated.

### Modifications

(1) The constituent member M whose temperature is measured by the member thermometer 70, which is the temperature measurer T, may be the heating target object B heated by the heater 50, and is not limited to the holding member 12 and the opposing surface 11a of the rotary table 11. In addition, the member thermometer 70 may measure the temperature of only the holding member 12 or only the rotary table 11.

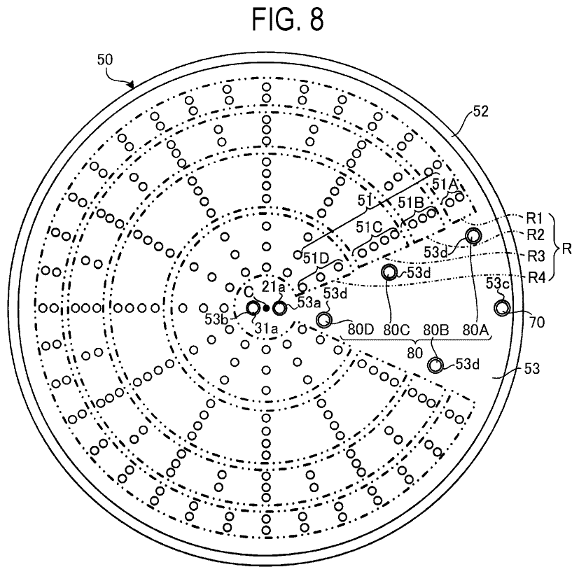

(2) In the above-described embodiment, the position of the temperature measurer T is such that the plurality of processing liquid thermometers 80 and the member thermometer 70 are arranged in a straight line along the radial direction of the support portion 52 (substrate W), but the positions of the processing liquid thermometers 80 and the member thermometer 70 are not limited thereto. The processing liquid thermometers 80 only need to correspond to the region heated by the heat source 51, and the member thermometer 70 only needs to correspond to the position of the holding member 12. They do not have to be arranged in a straight line. For example, as shown in FIG. 8, by allowing the processing liquid thermometers 80 and the member thermometer 70 to be spaced apart from each other, it is possible to reduce measurement errors due to stray light.

(3) A plurality of temperature measurers T may be provided. For example, member thermometers 70 may be arranged at all or some of the stop positions corresponding to the plurality of holding members 12. The member thermometers 70 for measuring the temperature of the holding members 12 and the member thermometer 70 for measuring the temperature of the opposing surface 11a may be provided separately.

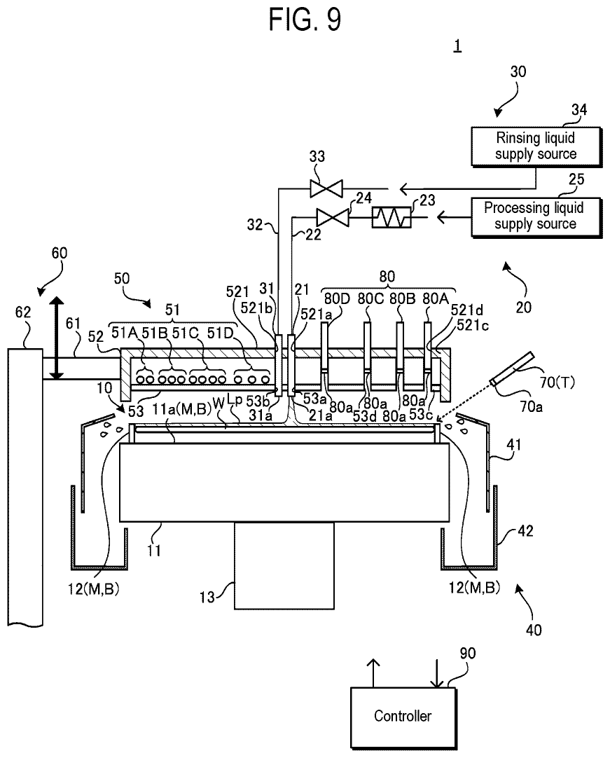

(4) The temperature measurer T does not have to be supported by the support portion 52 of the heater 50. For example, as shown in FIG. 9, the member thermometer 70 may be held outward of the support portion 52 and arranged at an angle with respect to the axis of rotation of the rotary holder 10 so as to be capable of measuring the temperature of the holding member 12. Such an embodiment is also included in the case where the temperature measurer T is arranged to face the rotary holder 10.

(5) The processing liquid thermometer 80 may serve as the temperature measurer T. That is, the heating target objects B may include the processing liquid Lp supplied to the rotating substrate W, and the temperature measurer T may include a processing liquid thermometer 80 configured to measure the temperature of the processing liquid Lp in a non-contact manner. In this case, the processing liquid thermometer 80 may be the same as, or may be different from the processing liquid thermometer 80 for controlling the heating temperature. For example, the processing liquid thermometer 80 may be provided as the temperature measurer T in addition to the above-mentioned processing liquid thermometers 80A to 80D.

In this case as well, it is preferable that the processing liquid thermometer 80 is a radiation thermometer, and the wavelength of the light emitted by the light emitting element serving as the heat source 51 is different from the measurement wavelength of the processing liquid thermometer 80. For example, when the processing liquid Lp is an aqueous solution including phosphoric acid, the light emitted by the light emitting element has a wavelength in a range of 350 nm to 1060 nm, and the measurement wavelength of the processing liquid thermometer 80 is 2.2 μm to 2.4 μm.

In this embodiment, when the temperature measured by the processing liquid thermometer 80 exceeds a preset temperature, the supply of electric power to the heater 50 is stopped. In this case, the preset temperature does not need to be the same as the preset temperature for the member thermometer 70. The preset temperature may be set to the temperature of the processing liquid Lp when the temperature of the constituent member M is close to its heat resistance temperature. In addition, the processing liquid thermometer 80 can measure the temperature of the processing liquid Lp on the substrate W when the rotary holder 10 holds the substrate W, and can measure the temperature of the opposing surface 11a of the rotary table 11 when the rotary holder 10 does not hold the substrate W. For this reason, the preset temperature may be different between when the temperature of the processing liquid Lp is being measured and when the temperature of the opposing surface 11a is being measured.

(6) The temperature measurer T may measure the temperature of the substrate W, and when the temperature of the substrate W exceeds a preset temperature, the stop controller 93 may stop the supply of electric power to the heater 50. In this case, a radiation thermometer may be used as the temperature measurer T. The preset temperature does not need to be the same as the preset temperature for the member thermometer 70. The preset temperature may be set to the temperature of the substrate W when the temperature of the constituent member M is close to its heat resistance temperature.

(7) In the above-described embodiment, the object to be heated by the heater 50, i.e., the object that is the target of heating and is directly heated, is the substrate W, and the processing liquid Lp in contact with the substrate W is indirectly heated. However, the heater 50 may also heat the processing liquid Lp. For example, the wavelength of the light emitted by the light emitting element as the heat source 51 may be set to the wavelength absorbed by the processing liquid Lp. In this case, the heating target object B that is the object to be measured by the temperature measurer T may be either the constituent member M or the processing liquid Lp.

(8) The processing performed by the substrate processing apparatus 1 is not limited to the etching process. Any processing apparatus that supplies the processing liquid Lp to the substrate W while heating the substrate W may be used. For example, a resist removal process that removes a resist film formed on the substrate W may be performed.

(9) The processing liquid Lp is not limited to the phosphoric acid solution. Any processing liquid Lp that requires heating may be used. For example, hydrofluoric acid or the like may be used. In addition, in the case of a resist removal process, an SPM (sulfuric acid/hydrogen peroxide solution) or the like may be used as the processing liquid Lp.

(10) The target substrate W may be a Si substrate having a resist formed on its surface. Furthermore, the substrate W is not limited to the Si substrate. For example, the substrate W may be a SiC substrate (silicon carbide wafer).

(11) The number, arrangement, and the like of the heat source 51 are not limited to those of the above-mentioned exemplary embodiment. In addition, the number of regions R may be more than one, and is not limited to four. Furthermore, the temperature measurement by the processing liquid thermometer 80 and the heating by the heat source 51 may not be controlled separately for the plurality of regions R. The light from the heat source 51 may be guided and emitted onto the substrate W via an optical fiber. Therefore, the heat source 51 does not have to be arranged above the substrate W. In addition, the heat source 51 may be any heat source that can heat the substrate W in a non-contact manner. For example, a light emitting element such as a highly directional laser diode may be used as the heat source 51. In addition, the heat source 51 is not limited to the light emitting element. For example, the heat source 51 may be a heater that performs resistance heating by supply of electric power.

(12) The support portion 52 on which the heat source 51 is arranged is a circular member having a diameter equal to or larger than the diameter of the substrate W. However, the support portion 52 is not limited thereto. The support portion 52 may be any type as long as the entire surface of the rotating substrate W can be irradiated with light. For example, the support portion 52 may be a rectangular member having a size that can cover the radius of the substrate W. If the portion of the substrate W corresponding to the radius thereof can be irradiated with light, the entire surface of the substrate W can be irradiated with light as the substrate W rotates. Furthermore, the support portion 52 may be provided so as to be swingable in the horizontal direction, and the entire surface of the substrate W may be irradiated with light by swinging the support portion 52 while emitting light from the heat source 51.

In this way, when the support portion 52 is smaller than the diameter of the substrate W, a mechanism for moving the processing liquid nozzle 21 in the horizontal direction may be provided so as to move the processing liquid nozzle 21 to above the substrate W when the processing liquid is supplied. In other words, the processing liquid nozzle 21 may be located anywhere as long as it can supply the processing liquid Lp toward the vicinity of the center of the substrate W while performing irradiation of light from the heat source 51.

The heat source 51 may be arranged so as to irradiate light onto the substrate W from below the substrate W to heat the substrate W. In this case, a support portion for supporting the heat source 51 may be provided on the opposing surface 11a of the rotary table 11 so as not to receive the rotation from the driver 13. Alternatively, a support that rotates at a different rotation speed with respect to the rotation speed (number of rotations per unit time) of the substrate W rotated by the rotary table 11 may be provided on the opposing surface 11a of the rotary table 11. However, it is preferable to irradiate the upper surface of the substrate W with the light emitted from the heat source 51 as in the above-described embodiment. This is because the heating can be performed starting from the interface with the processing liquid Lp.

(13) The processing liquid thermometer 80 only needs to be able to measure the temperature of the processing liquid Lp on the substrate W. For this reason, a mechanism for moving the support portion of the processing liquid thermometer 80 in the horizontal direction may be provided so as to move the processing liquid thermometer 80 to above the substrate W when measuring the temperature. A substrate thermometer for measuring the temperature of the substrate W may be provided, and the temperature controller 92 may control the temperature of the substrate W heated by the heater 50 based on the temperature of the substrate thermometer.

(14) In the above-described embodiment, the mechanism controller 91 and the temperature controller 92, which are control systems required for typical substrate processing, and the stop controller 93 and the notifier 94, which are control systems required for temperature monitoring to prevent overheating, are configured as a common controller 90. However, the stop controller 93 and the notifier 94 may be configured as another controller separate from the controller 90.

### OTHER EMBODIMENTS

The embodiments of the present disclosure and the modifications of the respective parts have been described above. The embodiments and the modifications of the respective parts are presented as examples and are not intended to limit the scope of the present disclosure. The novel embodiments described above may be implemented in various other forms. Various omissions, substitutions, combinations, and modifications may be made without departing from the gist of the present disclosure. Such embodiments and their modifications are included in the scope and gist of the present disclosure, and are included in the subject matters recited in the claims.

According to the present disclosure in some embodiments, it is possible to provide a substrate processing apparatus capable of preventing constituent members from being overheated.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a rotary holder configured to hold and rotate a substrate;
a processing liquid supply configured to supply a processing liquid to the substrate held and rotated by the rotary holder;
a heater including a heat source configured to heat the substrate or the processing liquid in contact with the substrate in a non-contact manner;
a temperature measurer arranged at a position facing the rotary holder and configured to measure a temperature of a heating target object heated by the heater in a non-contact manner; and
a stop controller configured to stop supply of electric power to the heater when it is determined that the temperature measured by the temperature measurer exceeds a preset temperature.

2. The substrate processing apparatus of claim 1, wherein the heating target object includes a constituent member constituting the rotary holder, and is heated together with the substrate or the processing liquid by the heater, and
wherein the temperature measurer includes a member thermometer configured to measure a temperature of the constituent member.

3. The substrate processing apparatus of claim 2, wherein the member thermometer is a radiation thermometer configured to measure the temperature of the constituent member based on light emitted from the constituent member of the rotary holder.

4. The substrate processing apparatus of claim 3, wherein the heat source is a light emitting element configured to emit light having a wavelength that is absorbed by the substrate, and
wherein the wavelength of the light emitted by the light emitting element is different from a measurement wavelength of the member thermometer.

5. The substrate processing apparatus of claim 4, further comprising:
a processing liquid thermometer configured to measure a temperature of the processing liquid supplied to the rotating substrate in a non-contact manner; and
a temperature controller configured to control a temperature of the substrate heated by the heater based on the temperature of the processing liquid measured by the processing liquid thermometer,
wherein the processing liquid thermometer is a radiation thermometer configured to measure the temperature of the processing liquid based on light emitted from the processing liquid, and
wherein a measurement wavelength of the processing liquid thermometer is different from the measurement wavelength of the member thermometer.

6. The substrate processing apparatus of claim 5, wherein the wavelength of the light emitted by the light emitting element is different from the measurement wavelength of the processing liquid thermometer.

7. The substrate processing apparatus of claim 6, wherein the processing liquid supplied by the processing liquid supply is an aqueous solution including phosphoric acid,
wherein the wavelength of the light emitted by the light emitting element is in a range of 350 nm to 1060 nm,
wherein the measurement wavelength of the processing liquid thermometer is 2.2 μm to 2.4 μm, and
wherein the measurement wavelength of the member thermometer is 8 μm to 14 μm.

8. The substrate processing apparatus of claim 1, wherein the heating target object includes the processing liquid supplied to the rotating substrate, and
wherein the temperature measurer includes a processing liquid thermometer configured to measure a temperature of the processing liquid in a non-contact manner.

9. The substrate processing apparatus of claim 8, wherein the heat source is a light emitting element configured to emit light having a wavelength that is absorbed by the substrate,
wherein the processing liquid thermometer is a radiation thermometer configured to measure the temperature of the processing liquid based on light emitted from the processing liquid, and
wherein the wavelength of the light emitted by the light emitting element is different from a measurement wavelength of the processing liquid thermometer.

10. The substrate processing apparatus of claim 9, wherein the processing liquid supplied by the processing liquid supply is an aqueous solution including phosphoric acid,
wherein the wavelength of the light emitted by the light emitting element is in a range of 350 nm to 1060 nm, and
wherein the measurement wavelength of the processing liquid thermometer is 2.2 μm to 2.4 μm.

11. The substrate processing apparatus of claim 2, wherein the rotary holder includes a holding member configured to hold the substrate, and
wherein the member thermometer is provided at a position facing the holding member of the rotary holder when the rotary holder is stopped.

12. The substrate processing apparatus of claim 2, wherein the rotary holder includes an opposing surface facing the substrate, and
wherein the member thermometer is provided at a position facing the opposing surface.

13. The substrate processing apparatus of claim 2, wherein the heat source includes a plurality of heat sources provided in regions corresponding to different radial positions of the substrate,
wherein output of each of the plurality of heat sources is controlled for each of the regions, and
wherein the member thermometer is provided at a position capable of measuring a temperature of a vicinity of an outermost periphery of the regions heated by the plurality of heat sources.
